(19) United States
(12) Patent Application Publication
(10) Pub. No.: US 2015/0050873 A1
(43) Pub. Date: Feb. 19, 2015

(54) VENTILATION OF AN ELECTRICAL DEVICE

(71) Applicant: SIEMENS AKTIENGESELLSCHAFT, MUENCHEN (DE)

(72) Inventor: Georg Dengler, Hirschaid (DE)

(21) Appl. No.: 14/396,121

(22) PCT Filed: Apr. 2, 2013
(86) PCT No.: PCT/EP2013/056882

§ 371 Date: Oct. 22, 2014

(30) Foreign Application Priority Data
Apr. 27, 2012 (DE) 102012207013.3

(51) Int. Cl. H05K 7/20; B61D 27/00

(52) U.S. Cl. CPC H05K 7/20845; B61D 27/009
USPC 454/108; 454/184

(57) ABSTRACT

An electrical device contains a metal device housing and at least one electrical component which is located in the metal device housing. Accordingly, there is an opening in the metal device housing, in which opening a ventilation element is inserted, which enables ventilation of the device housing interior through at least one ventilation channel of the ventilation element. The ventilation element has a material that increases in volume in the event of heating when an activation temperature is reached and thus closes the at least one ventilation channel.

The invention relates to an electrical device comprising a metal device housing and at least one electrical component which is located in the metal device housing.

The invention is based on the object of specifying an electrical device which allows the interior of the device to be ventilated and vented and, in spite of this, ensures adequate fire protection in the event of a fire.

According to the invention, this object is achieved by an electrical device having the features as claimed in patent claim 1. Advantageous refinements of the electrical device according to the invention are specified in dependent claims.

Accordingly, the invention makes provision for there to be an opening in the metal device housing, a ventilation element which allows the interior of the device housing to be ventilated and vented through at least one aeration channel of the ventilation element being inserted into said opening, wherein the ventilation element is composed of a material of which the volume increases, and as a result the at least one aeration channel closes, when an activation temperature is reached in the event of said material being heated.

A significant advantage of the electrical device according to the invention is that it is possible to ventilate and vent the interior of the device owing to the use of the ventilation element which is provided according to the invention. Ventilation or venting in this way advantageously makes it possible to prevent water of condensation forming in the interior of the device or to discharge water of condensation, which has been produced, again by ventilation and venting.

A further significant advantage of the electrical device is that adequate fire protection is ensured in spite of the presence of an opening in the device housing. If, specifically, the device catches fire, the material which is provided according to the invention reaches a prespecified activation temperature and then its volume increases; this leads to the ventilation element being closed, so that said ventilation element is hermetically sealed. Therefore, supply of oxygen and therefore boosting of the fire within the electrical device are prevented.

Since particularly stringent requirements in respect of fire protection are in place in the vehicle sector, in particular in the rail vehicle sector, it is considered to be advantageous when the electrical device forms a component of a vehicle, in particular of a rail vehicle.

The electrical device is preferably arranged within the vehicle.

The electrical device preferably contains a drive component or an electrical actuation component for a drive component of the vehicle.

The electrical device can form, for example, a switchgear cabinet which contains at least one electrical switching element. As an alternative or in addition, the electrical device can form a distributor cabinet which contains at least one electrical distributor element.

The material of which the volume increases when the activation temperature is reached preferably expands when it is heated. The material is preferably an intumescent material.

In order to allow the aeration channel to be reliably closed, it is considered to be advantageous when the at least one aeration channel, at least in sections, is arranged in the material and passes through said material.

In order to allow the ventilation element to be fitted in the opening in the device housing in a simple manner, it is considered to be advantageous when the ventilation element comprises a metal ring which is inserted into the opening in the metal device housing, and when the metal ring supports the material.

The air is preferably deflected through at least 180° in the aeration channel. In a refinement of this kind, it is advantageously possible for the ingress of water into the interior of the device to be made more difficult.

According to a particularly preferred refinement of the electrical device, provision is made for the aeration channel to have at least one inner channel opening on the inside of the device and at least one outer channel opening on the outside of the device, and for the channel openings to not overlap as seen perpendicular to the opening area of the opening in the device housing.

The invention further relates to a rail vehicle comprising an electrical device. According to the invention, provision is made for there to be an opening in a metal device housing of the electrical device, a ventilation element which allows the interior of the device housing to be ventilated and vented through at least one aeration channel of the ventilation element being inserted into said opening, wherein the ventilation element has a material of which the volume increases, and as a result the at least one aeration channel closes, when an activation temperature is reached in the event of said material being heated.

In respect of the advantages of the rail vehicle according to the invention, reference should be made to the above statements in connection with the electrical device according to the invention since the advantages of the electrical device according to the invention substantially correspond to those of the rail vehicle according to the invention.

The invention further relates to a method for ventilating an electrical device comprising a metal device housing in which at least one electrical component is located. In respect of a method of this kind, provision is made, according to the invention, for the interior of the device housing to be ventilated and vented by an aeration channel in a ventilation element, which is inserted into an opening in the metal device housing, provided that the temperature in the region of the ventilation element is below a prespecified activation temperature, and the at least one aeration channel is closed due to an increase in the volume of a material of the ventilation element when the prespecified activation temperature is reached or exceeded.

In respect of the advantages of the method according to the invention, reference should be made to the above statements in connection with the electrical device according to the invention since the advantages of the electrical device according to the invention substantially correspond to those of the method according to the invention.

The invention will be explained in greater detail below with reference to exemplary embodiments in which, by way of example,

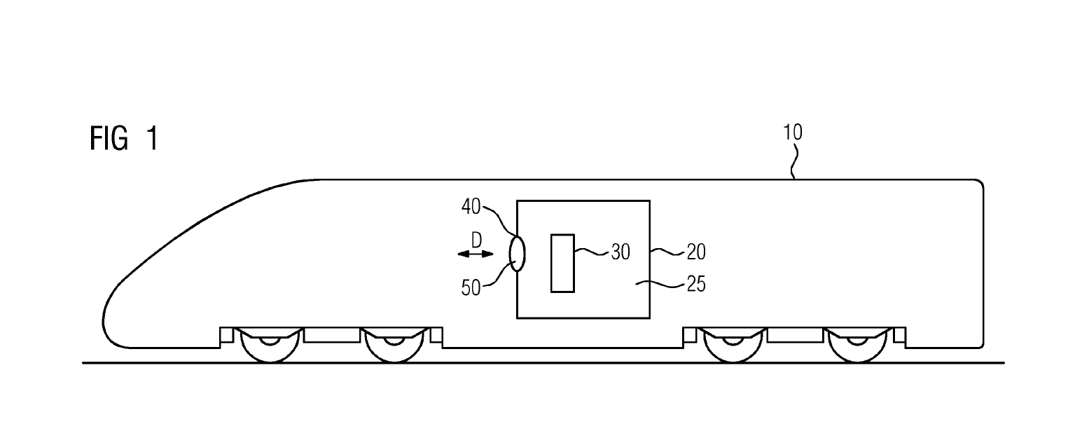

FIG. 1 shows an exemplary embodiment of a rail vehicle according to the invention which is equipped with an exemplary embodiment of an electrical device according to the invention,

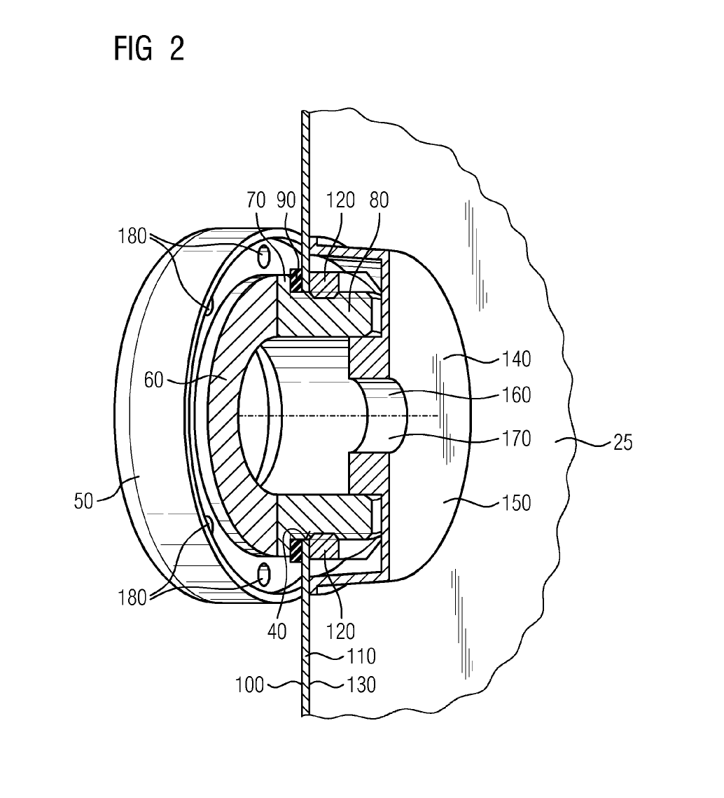

FIG. 2 shows an exemplary embodiment of a ventilation element which can be used in the electrical device according to FIG. 1,

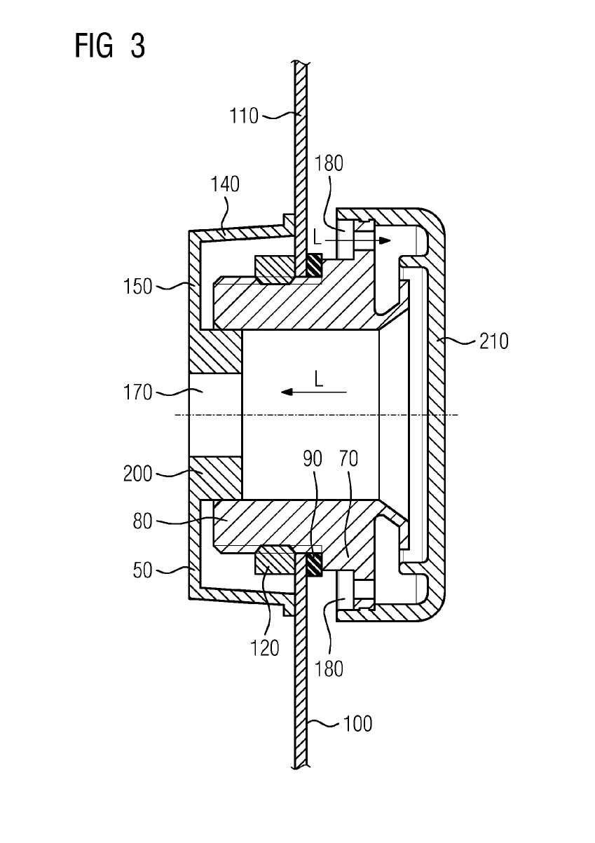

FIG. 3 shows the ventilation element according to FIG. 2 in cross section after it is fitted in a device housing opening,

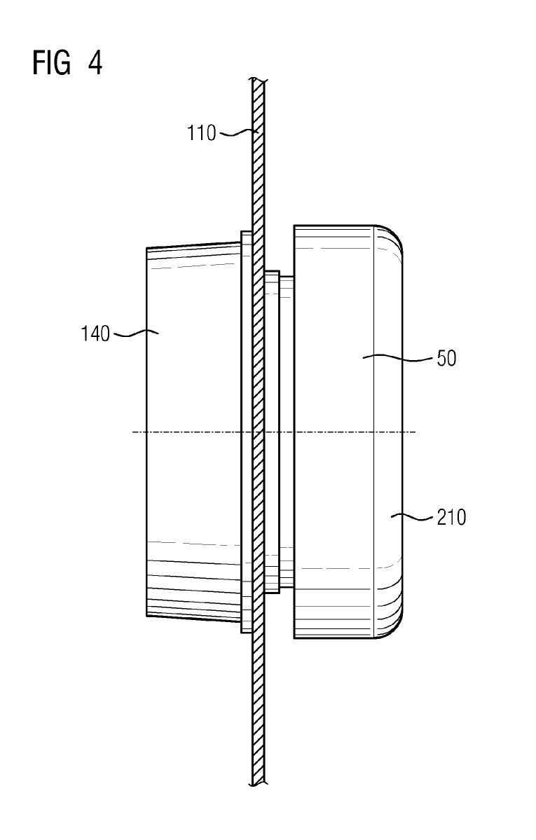

FIG. 4 shows the ventilation element according to FIG. 2 in a view from the side after it is fitted in a device housing opening,

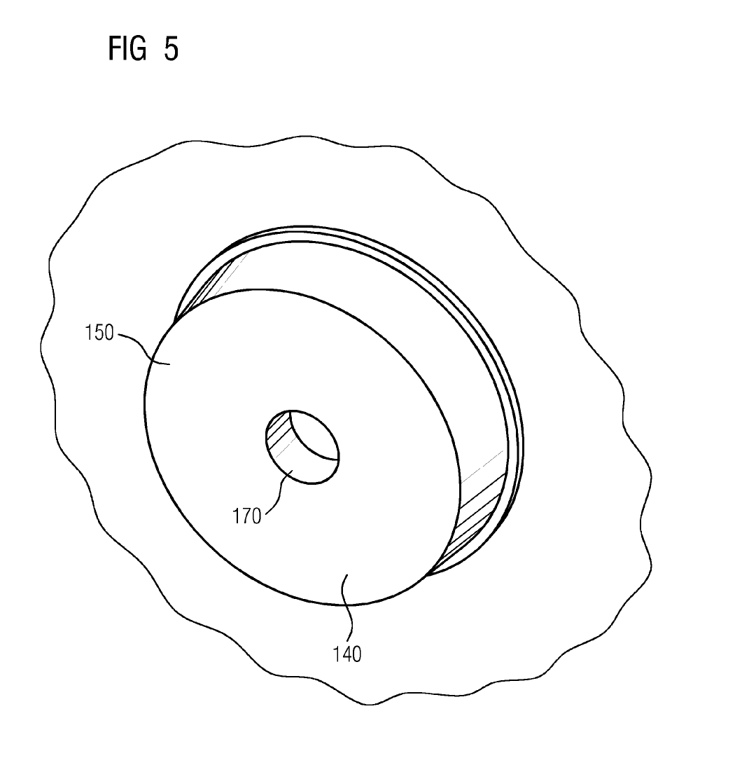

FIG. 5 shows the ventilation element according to FIG. 2 after it is fitted in a device housing opening, wherein a view from the interior of the housing is shown, and

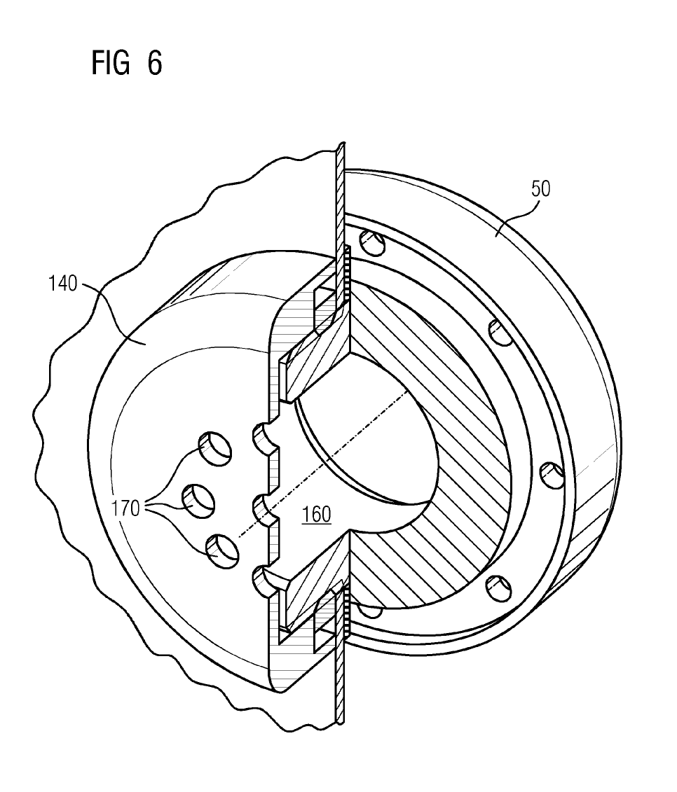

FIG. 6 shows a second exemplary embodiment of a ventilation element according to the invention which can be used in the electrical device according to FIG. 1.

For the sake of clarity, the same reference symbols are always used for identical or comparable components in the figures.

FIG. 1 shows a rail vehicle 10 which is equipped with an electrical device 20. An actuation component 30 for a drive component of the rail vehicle 10, said drive component not being illustrated further for reasons of clarity, is located in the interior of the device, that is to say in the interior of the metal housing 25 of the electrical device 20. The actuation component 30 may be, for example, a switch, for example a semiconductor switch, and/or a converter.

FIG. 1 further shows that there is an opening 40 in the metal device housing 25, a ventilation element 50 being inserted into said opening. The ventilation element 50 allows the interior of the device housing to be ventilated and vented through at least one aeration channel. The ventilation and venting of the interior of the device housing is schematically indicated by a double-headed arrow bearing the reference symbol D in FIG. 1.

FIG. 2 shows an exemplary embodiment of a ventilation element 50 which is inserted into the opening 40 in the metal device housing 25 (cf. FIG. 1).

The ventilation element 50 comprises a metal ring 60 which comprises a flange section 70 and also a screw section 80. The flange section 70 is situated on a sealing ring 90 which is arranged between the flange section 70 and the outside 100 of the housing wall 110 of the metal device housing 25.

The screw section 80 of the metal ring 60 extends through the opening 40 in the housing wall 110 of the metal device housing 25 and is fixed in the opening 40 by means of a nut 120. Said figure shows that the nut 120 bears on the inside 130 of the housing wall 110 of the device.

FIG. 2 further shows an inner cap 140 which is composed of an expandable or intumescent material 150. If the material 150 of the inner cap reaches a prespecified activation temperature, the volume of the material 150 increases due to expansion.

An aeration channel 160 which has an inner channel opening 170 on the inside of the device and also has a large number of outer channel openings 180 on the outside 100 of the device extends through the ventilation element 50. It is possible to ventilate and vent the interior of the electrical device 20 according to FIG. 1 through the aeration channel 160 and/or through the outer channel openings 180 and the inner channel opening 170.

FIG. 2 shows that the aeration channel 160 extends through the inner cap 140 and therefore through the expandable material 150; this is because the inner channel opening 170 is located in the region of the inner cap 140.

If there is a fire in the interior of the electrical device 20 according to FIG. 1, the incident heating causes the material 150 of the inner cap 140 to reach its activation temperature and expand, as a result of which the inner channel opening 170 is closed and the aeration channel 160 is blocked. Therefore, further ventilation or venting of the interior of the device is suppressed, so that, in association with this, no oxygen can enter the interior of the device from the outside either. Therefore, reliable fire protection and/or reliable fire fighting is made possible owing to the expansion and the closure of the aeration channel 160 in the event of a fire.

As further shown in FIG. 2, the outer channel openings 180 in the aeration channel 160 face the housing wall 110 of the metal device housing 25. Air which attempts to flow into the interior of the device from the outside through the aeration channel 160, or conversely from the interior of the device to the outside, is therefore deflected through 180° in the aeration channel 160.

FIG. 3 shows the ventilation element 50 according to FIG. 2 in cross section. Said figure shows the inner cap 140 which is composed of the material 150 and which is inserted into the screw section 80 of the metal ring 60 by way of an annular fastening section 200 and is therefore held by the metal ring 60.

Said figure further shows the nut 120 which is screwed onto the screw section 80 of the metal ring 60 and, together with the flange section 70, holds the ventilation element 50 against the housing wall 110.

The sealing ring 90, illustrated in FIGS. 2 and 3, between the flange section 70 and the outside 100 of the housing wall 110 of the device is advantageous in order to allow the ventilation element 50 in the opening 40 to be reliably sealed off. In spite of this, the sealing ring 90 is not absolutely necessary; the flange section 70 could, as an alternative, also bear directly on the outside 100 of the housing wall 110 of the device.

FIG. 3 further shows the outer channel openings 180 which face the outside 100 of the housing wall 110 of the device. Said figure shows that air L, which attempts to flow into the interior of the device from the outside, is deflected through approximately 180° within the outer cover section 210 of the ventilation element 50 before it reaches the inner channel opening 170 in the inner cap 140 of the ventilation element 50. The air in the aeration channel 160 is deflected in a corresponding manner in the event of air flowing from the interior of the housing to the outside through the ventilation element 50.

FIG. 4 shows the ventilation element 50 according to FIGS. 2 and 3 in a view from the side. Said figure shows the positioning of the inner cap 140 and that of the cover section 210 of the ventilation element 50 relative to the housing wall 110 of the metal device housing 25.

FIG. 5 once again shows, in a three-dimensional view of the interior of the device, an illustration of the inner cap 140 which is composed of the expandable or intumescent material 150. Said figure shows the inner channel opening 170 which cooperates with the outer channel openings, not shown in FIG. 5, (cf. FIG. 2) of the ventilation element 50.

FIG. 6 shows a second exemplary embodiment of a ventilation element 50 as can be used in the electrical device 20 according to FIG. 1.

In contrast to the exemplary embodiment according to FIGS. 2 to 5, the inner cap 140 is equipped with a plurality of holes, which form inner channel openings 170 in the aeration channel 160, in the ventilation element 50 according to FIG. 6. Therefore, a plurality of inner channel openings 170 are available to the air, which passes the aeration channel for ventilation or venting purposes, at the interface to the interior of the device.

Otherwise, the exemplary embodiment according to FIG. 6 corresponds to the exemplary embodiment according to FIGS. 2 to 5.

Although the invention has been described and illustrated in detail by preferred exemplary embodiments, the invention is not restricted by the disclosed examples and other variations can be derived from said examples by a person skilled in the art, without departing from the scope of protection of the invention.

1-15. (canceled)

16. An electrical device, comprising:
a metal device housing having an opening formed therein and an interior;
at least one electrical component disposed in said metal device housing; and
a ventilation element having at least one aeration channel, said ventilation element allowing said interior of said metal device housing to be ventilated and vented through said at least one aeration channel of said ventilation element disposed in said opening of said metal device housing, said ventilation element having a material of which a volume increases when an activation temperature being reached in an event of said material being heated, and resulting in said at least one aeration channel being closed by said material.

17. The electrical device according to claim 16, wherein the electrical device forms a component of a vehicle.

18. The electrical device according to claim 17, wherein the electrical device is formed to be disposed within the vehicle.

19. The electrical device according to claim 16, further comprising a drive component or an electrical actuation component for said drive component of a vehicle.

20. The electrical device according to claim 16, wherein the electrical device is a switchgear cabinet containing at least one electrical switching element.

21. The electrical device according to claim 16, wherein the electrical device is a distributor cabinet containing at least one electrical distributor element.

22. The electrical device according to claim 16, wherein said material expands when said material is heated.

23. The electrical device according to claim 16, wherein said material is a intumescent material.

24. The electrical device according to claim 16, wherein said at least one aeration channel, at least in sections, is disposed in said material and passes through said material.

25. The electrical device according to claim 16, wherein said ventilation element has a metal ring inserted into said opening in said metal device housing, and said metal ring supports said material.

26. The electrical device according to claim 16, wherein air is deflected through at least 180° in said at least one aeration channel.

27. The electrical device according to claim 16, wherein:
said at least one aeration channel has at least one inner channel opening on an inside of the electrical device and at least one outer channel opening on an outside of the electrical device; and
said inner and outer channel openings do not overlap as seen perpendicular to an opening area of said opening in said metal device housing.

28. The electrical device according to claim 17, wherein said vehicle is a rail vehicle.

29. A rail vehicle, comprising:
an electrical device, containing:
a metal device housing having an opening formed therein and an interior;
at least one electrical component disposed in said metal device housing; and
a ventilation element having at least one aeration channel, said ventilation element allowing said interior of said metal device housing to be ventilated and vented through said at least one aeration channel of said ventilation element disposed in said opening of said metal device housing, said ventilation element having a material of which a volume increases when an activation temperature being reached in an event of said material being heated, and resulting in said at least one aeration channel being closed by said material.

30. A method for ventilating an electrical device having a metal device housing in which at least one electrical component is disposed, which comprises the steps of:
ventilating an interior of the metal device housing via an aeration channel of a ventilation element being disposed in an opening in the metal device housing, provided that a temperature in a region of the ventilation element is below a prespecified activation temperature; and
closing the at least one aeration channel due to an increase in a volume of a material of the ventilation element when the prespecified activation temperature is reached or exceeded.

31. The method according to claim 30, wherein the at least one aeration channel is closed due to a thermally induced expansion of the material when the prespecified activation temperature is reached or exceeded.
